(19) United States
(12) Patent Application Publication
(10) Pub. No.: US 2004/0030984 A1
(43) Pub. Date: Feb. 12, 2004

(54) Method for decoding a block of symbols and device therefor

(76) Inventor: Christine Renaud, Rueil-Malmaison (FR)

Correspondence Address: Dan C Hu, Trop Pruner & Hu, 8554 Katy Freeway, Suite 100, Houston, TX, 77024, US

(21) Appl. No.: 10/432,153

(22) PCT Filed: Nov. 14, 2001
(86) PCT No.: PCT/FR01/03572

(30) Foreign Application Priority Data
Nov. 27, 2000 (FR) 00/15266

(51) Int. Cl. H03M 13/00

(52) U.S. Cl. 714/784

(57) ABSTRACT

The invention concerns a method for decoding a block of input symbols, protected for example by a Reed-Solomon code, which consists in calculating error syndromes and in applying a first error correction method, having the calculated symbols as input parameters, so as to estimate the information symbols. In response to a correction incapacity indication by the first method, it consists in applying a second error correction and erasure method, having the calculated syndromes and at least an erasing position in the block as input parameters, so as to estimate the information symbols.

The present invention relates to techniques for decoding of the redundancy codes used to protect digital information against errors liable to appear during its transmission or its storage.

The present invention applies in particular to Reed-Solomon type codes commonly used for this purpose.

We consider for example a Reed-Solomon code RS(N, N−2t, t) defined over a finite field, or Galois field, GF(2^{m}) with cardinal 2^{m}. A Reed-Solomon code is a blockwise cyclic code whose generating polynomial g(x) of degree 2t, with coefficients in GF(2^{m}), has as roots 2t consecutive powers of a primitive element a of the field GF(2^{m}):

$$g ( x ) = {\prod }_{i = 1}^{2 t} ( x - {α}^{i} ) \qquad ( 1 )$$

Each code word is composed of N symbols (N<2^{m}) of the field GF(2^{m}) which represent N−2t independent information symbols. The number t is the maximum number of erroneous symbols that can be corrected algebraically using the code without a priori information about their positions. Each block received by the decoder is composed of N symbols of GF(2^{m})r₀, r₁, . . . , r_{N-1} defining the polynomial:

R(x)=r_{N}₁₋₁x^{N-1}x+ . . . +r₁ . . . x+r₀ (2)

In the absence of errors in the symbols received, the generating polynomial of the code g(x) is a factor of this polynomial R(x).

The decoding processes generally involve calculations of error syndromes. A syndrome is a value of the polynomial R(x) for a given element of the Galois field. Usually, one limits oneself to the calculation of the syndromes for the 2t roots of the generating polynomial of the code: Si=R(α¹) for 1≦i≦2t. If the block received comprises V erroneous symbols rₕ₍₀₎,rₕ₍₁₎, . . . , rₕ₍ᵥ₋₁₎, with V≦t and 0≦h(v)<N for 0≦v<V, then each syndrome Si satisfies:

$${S}_{i} = {\sum }_{v = 0}^{V - 1} {α}^{i \cdot h ( v )} \cdot {e}_{h ( v )} \qquad ( 3 )$$

where eₕ₍ᵥ₎ denotes the amplitude of the error in the symbol rₕ₍ᵥ₎.

A conventional way of calculating a syndrome Sᵢ is to use a recursive procedure or a circuit consisting essentially of a multiplier, an adder and a register for implementing the recurrence relation

S_{I}⁽ⁿ⁾=Sᵢ⁽ⁿ⁻¹⁾αⁱ+r_{N-1-n} (4)

With the initialization condition Sᵢ⁽⁰⁾=r_{N-1}, the syndrome Sᵢ can be calculated in tandem with the arrival of the symbols r_{N-1-n} (in the order of decreasing weights), and obtained as soon as the last symbol r₀ of the block arrives:

Sᵢ=Sᵢ^{(N-1)}.

The 2t relations (3) have 2V unknowns, namely the positions h(v) and the amplitudes eh(V) of the errors. To solve these equations, most of the decoding algorithms involve the calculation of an error locator polynomial a(x) of degree V whose roots are the elements of the Galois field of the form α^{-h(v)}. The expression for the error locator polynomial is:

$$σ ( x ) = κ \cdot {\prod }_{v = 0}^{V} ( 1 - x \cdot {α}^{h ( v )} ) = {σ}_{t} \cdot {x}^{t} + {σ}_{t - 1} \cdot {x}^{t - 1} + … + {σ}_{1} \cdot x + {σ}_{0} \qquad ( 5 )$$

where κ=σ₀ is an arbitrary element of the field GF(2^{m}) and σᵤ=0 for u>V. The coefficients σᵤ of this polynomial satisfy the linear system:

$$( \begin{matrix}{S}_{1} & {S}_{2} & ⋯ & {S}_{V} \\ {S}_{2} & {S}_{3} & & {S}_{V + 1} \\ ⋮ & & ⋰ & ⋮ \\ {S}_{V} & {S}_{V + 1} & ⋯ & {S}_{2 V - 1}\end{matrix} ) \cdot ( \begin{matrix}{σ}_{V} \\ {σ}_{V - 1} \\ ⋮ \\ {σ}_{1}\end{matrix} ) \approx - κ \cdot ( \begin{matrix}{S}_{V + 1} \\ {S}_{V + 2} \\ ⋮ \\ {S}_{2 V}\end{matrix} ) \qquad ( 6 )$$

Various algorithms exist for solving the linear system (6), in particular Euclid's algorithm and the Berlekamp-Massey type algorithms. Euclid's algorithm is conceptually simple, but its implementation requires a greater complexity than the Berlekamp-Massey type algorithms. The Berlekamp-Massey type algorithms solve the system (6) through successive iterations which are conventionally interpreted as a recursive construction of a shift register with linear operators modeling the system (see “Theory and Practice of Error Control Codes” by R. E. Blahut, Addison-Wesley, Reading, Mass., 1993). At each iteration, a prediction discrepancy Δₖ with values in the field GF(2m) is calculated so as to update the locator polynomial. If this discrepancy Δₖ is still nonzero on completion of the (2t)-th iteration, the algorithm indicates a decoding failure, the block received comprising more than t erroneous symbols.

Various alternatives of the Berlekamp-Massey algorithm have been proposed with the aim of simplifying its implementation. The article “VLSI Design of Inverse-Free Berlekamp-Massey Algorithm”, by I.S. Reed at al, IEEE Proceedings-E Vol. 138, No 5, September 1991, pages 295-298, proposes an interesting alternative in so far as it makes it possible to get out of inverting the prediction discrepancies Δₖ. This alternative amounts to considering any a priori value in GF(2^{m}) for the coefficient κ=σ₀, instead of κ=1 in the traditional version.

Once the error locator polynomial has been calculated, its roots are determined so as to obtain the positions h(v) of the errors. A procedure frequently used for this, the so-called “Chien search”, consists in calculating the values of the polynomial a(x) for each of the elements of the field GF(2^{m}), an error being identified whenever σ(x)=0 (see “Cyclic Decoding Procedure for the Bose-Chaudhuri-Hocquenghem Codes” by R. T. Chien, IEEE Trans. on Information Theory, Vol. 10, 1964, pages 357-363). This procedure consists of a recursive calculation of the values σ(α^{1-N+n}) for n=0, 1, . . . , N−1 according to:

$$σ ( {α}^{1 - N + n )} = {\sum }_{u = 0}^{t} {ζ}_{u}^{( n )} \qquad ( 7 )$$

by utilizing the recurrence relations ζᵤ⁽ⁿ⁺¹⁾=ζᵤ⁽ⁿ⁾α″ for 0≦u≦t, initialized by ζᵤ⁽⁰⁾=σᵤ.α^{u.(1-N)}.

The amplitudes of the errors are for example evaluated according to Formey's algorithm (See “On Decoding BCH Codes”, by G. D. Formey, IEEE Trans. on Information Theory, Vol. 11, 1965, pages 549-557). An error evaluator polynomial (o(x) is defined by:

ω(x)=[S(x).σ(x)] modulo x^{2t}=ωₜ.x^{t}+ωₜ₋₁.x¹⁻¹+ . . . +ω₁x+ω₀ (8)

S(x) denoting the syndromes polynomial:

$$S ( x ) = {\sum }_{i = 1}^{2 t} {S}_{i} \cdot {x}^{i} \qquad ( 9 )$$

The amplitudes of the errors are then obtained by:

$${θ}_{h ( v )} = \frac{ω ( x )}{x \cdot {σ}^{t} ( x )} for x = {α}^{- h ( v )} \qquad ( 10 )$$

σ′(x) denoting the derivative of the error locator polynomial. The values of the denominator σ^{1-N+n}.σ′ (α^{1-N+n}) for n=0, 1, . . . , N−1 can be obtained simply during the Chien search (through a sum such as (7) in which only the terms for u odd are summed). The values of the numerator can be obtained through a procedure similar to the Chien search on replacing au by ωᵤ in the initialization of the recurrence relations.

When the decoder uses a Berlekamp-Massey type algorithm, the coefficients of the evaluator polynomial ω(x) can be calculated at the same time as those of the locator polynomial during the 2t iterations of this algorithm. They can also be calculated later according to (8).

Certain decoding algorithms have been devised to be able to take account of the erasures in the input data. An erased symbol is marked in the input block so as to indicate that this symbol has not been received or that it has been received under such poor conditions that its value is a priori false. By taking these erasures into account it is possible to reduce the number of unknowns in relations (3) since some of the positions h(v) are known.

When the error locator polynomial is calculated iteratively according to the Berlekamp-Massey algorithm, the taking of the erasures into account leads to the coefficients of the locator polynomial σ(x) being initialized differently before the first iteration. In a coding without erasures, this locator polynomial is customarily initialized by σ⁰(x)=1, whereas the taking of the erasures into account leads to it being initialized by a polynomial of degree s whose roots α^{-h(0)}, . . . , α^{-h(s-1)}, are determined by the positions h(0), . . . , h(s−1) of the s erasures considered. The Berlekamp-Massey algorithm adapted to take account of the erasures is also described in the aforesaid work by R. E. Blahut. A version adapted so as to get out of the inverse calculations in the Galois field is described in the article “On Decoding of Both Errors and Erasures of a Reed-Solomon Code Using an Inverse-Free Berlekamp-Massey Algorithm”, by J. H.JENG et al., IEEE Transactions on Communications, Vol. 47, No. 10 October 1999, pages 1488-1494.

If s is the number of erased symbols of the input block and V the number of erroneous symbols, the decoding algorithm with handling of erasures makes it possible to correct the errors and the erasures of the block if 2s+V≦2t, i.e. s+V/2≦t

This last advantage constitutes the attraction of algorithms with erasures, which may go so far as to double the correction capability of the code if 2t errors have been erased.

However this advantage assumes that the determination of the erased symbols is perfectly reliable. In practice, this condition is not always fulfilled. In particular, there is a probability of erasing symbols which turned out to have been received properly. In such a case, if the number of erroneous symbols was originally less than or equal to t, the correction capabilities of the algorithm with erasures may be exceeded whereas the algorithm without erasure would have provided the right result.

An aim of the present invention is to optimize the decoding capabilities of error corrector codes such as the Reed-Solomon or BCH (Bose-Chaudhuri-Hocquenghem) type codes.

The invention thus proposes a method of decoding a block of input symbols, wherein syndromes are calculated from the block, in conjunction with an error corrector code, and a first process of correction of errors, having the calculated syndromes as input parameters, is applied so as to estimate information symbols. In response to an indication of inability to correct by the first process, a second process of correction of errors and of erasures, having the calculated syndromes and at least one erasure position in the block as input parameters, is applied so as to estimate the information symbols.

This method alleviates the limitation alluded to hereinabove of the algorithms with handling of erasures, while guaranteeing that the decoding always takes place under good conditions when the input block does not comprise more than t erroneous symbols. In certain cases where there are more than t erroneous symbols, the second decoding with erasure will allow the right correction.

The decoding proposed therefore takes into consideration a probability of being mistaken in the positioning of the erasures. The scheme is therefore suitably adapted to methods for receiving signals with low signal/noise ratio.

It should be noted that there is no need to calculate the syndromes twice when the two correction procedures are to be applied to the same block. As the calculation of the syndromes represents a considerable proportion of the complexity of the decoding as a whole (around 50%), the gain afforded by the method is achieved at the price of a reasonable increase in complexity.

Another aspect of the present invention pertains to a signal processing device, comprising means for receiving the signal so as to estimate blocks of input symbols and means for decoding said blocks by means of an error corrector code. The means for receiving the signal are designed to provide information about the reliability of the input symbols of the block. The decoding means comprise means for calculating syndromes from a signal block, first means for processing the syndromes so as to estimate information symbols, means for determining at least one erasure position in the block on the basis of said information about the reliability, and second means for processing the syndromes and said at least one erasure position, which means are activated in response to an indication of inability to correct by the first processing means, so as to estimate the information symbols.

Other features and advantages of the present invention will become apparent in the description hereinbelow of nonlimiting exemplary embodiments, with reference to the appended drawings, in which:

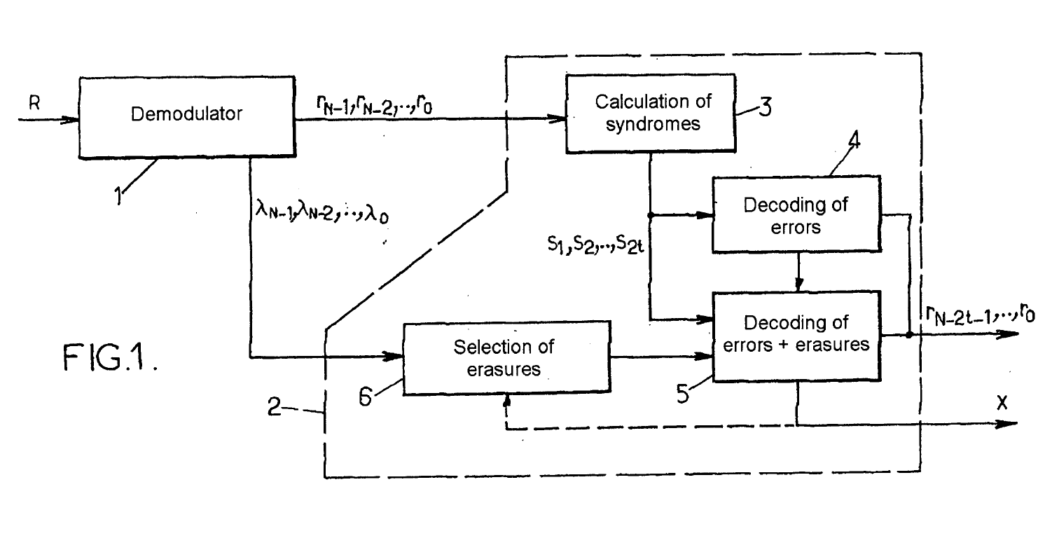

FIG. 1 is a schematic diagram of an example of a device according to the invention; and

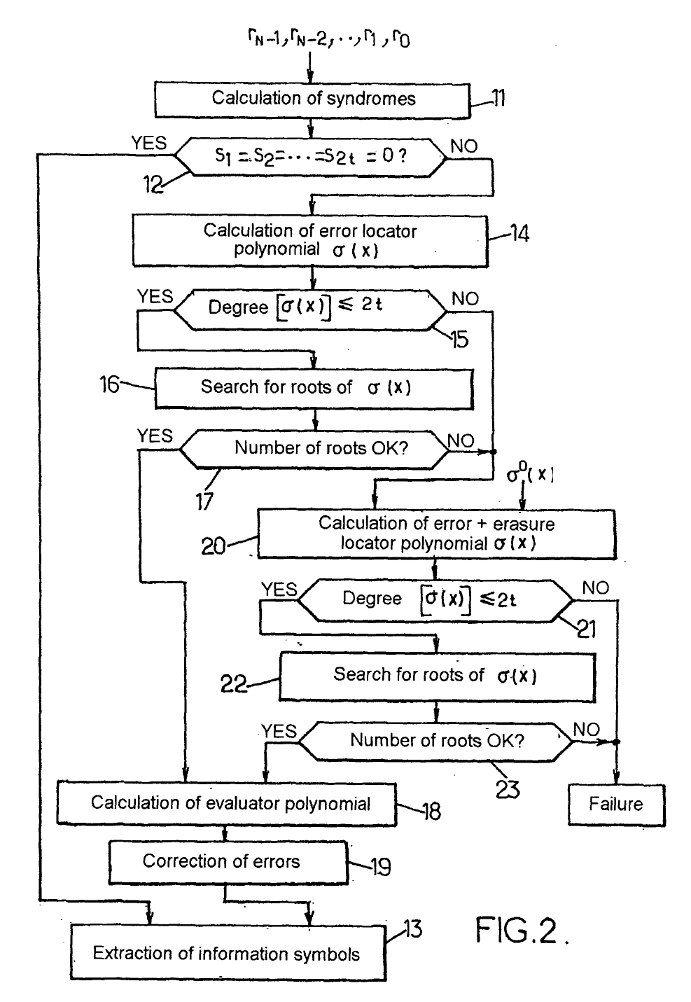

FIG. 2 is a flowchart illustrating a decoding method according to the invention.

The device represented in FIG. 1 processes an input digital signal R which it has been possible for example to transmit on a radio interface. This signal R is provided to a demodulator 1 which undertakes an estimation of digital symbols transmitted. These digital symbols have been generated at the level of a transmitter (not represented) by applying a redundancy coding, so as to protect the information symbols against transmission errors. The redundancy code is preferably a nonbinary Reed-Solomon code such as presented in the introduction.

For convenience of realization, one generally uses systematic codes, that is to say where the N−2t information symbols lie explicitly in the N symbols transmitted. They are for example the first N−2t symbols.

The demodulator 1 provides the estimated symbols r_{N-1}, r_{N-2}, . . . ,r₁, r₀ in blocks of N symbols to a decoder 2. Each symbol consists of m bits when the Reed-Solomon code is defined over the field CF(2^{m}).

The decoder 2 comprises a module 3 for calculating syndromes, which calculates the 2 t error syndromes S₁, S₂, . . . , S₂ₜ, in a conventional manner, for example according to relation (4).

The decoder 2 furthermore comprises a module 4 for decoding errors without taking erasures into account. The latter module can operate in a conventional manner according to the Berlekamp-Massey, Chien and Formey algorithms so as to correct possible errors, fewer than or equal to t in number, in the estimated symbols of the input block. The first N−2t symbols are extracted after correction so as to be provided to utilization circuits situated downstream.

Another decoding module 5 of the decoder 2 takes into account errors and also erasures when the first module 4 indicates that it has been unable to correct the block owing to the detection of a number greater than t of errors. The module 5 operates by using the same syndromes S₁, . . . ,S₂ₜ which have been calculated by the module 3, and by initializing the error locator polynomial according to an initialization polynomial σ⁰(x) provided by an erasures selection module 6.

If the decoding module 5 is also stumped, it delivers an alarm signal X to indicate the loss of a block to the circuits situated downstream.

The erasures selection module 6 operates in a known manner on the basis of likelihood measures λ_{N-1}, λ_{N-2}, . . . , λ₁, λ₀ provided by the demodulator 1 in parallel with the estimated symbols r_{N-1}, r_{N-2}, . . . r₁, r₀. These likelihood measures have for example been produced using the metric of a channel equalizer with soft outputs of the demodulator 1 (see for example EP-A-0 946 014).

Using the positions of the erased symbols, the module 6 calculates the initialization polynomial σ⁰(x) for the Berlekamp-Massey algorithm implemented by the decoding module 5.

FIG. 1 gives a schematic representation of the device according to the invention. In practice, the decoder 2 will often be realized by programming a digital signal processor appropriately, for example according to the flowchart of FIG. 2.

The first step of the processing of a block r_{N-1}, r_{N-2}, . . . , r₁, r₀ is the calculation 11 of the syndromes S₁, S₂, . . . , S₂ₜ according to relations (4). If all the syndromes are zero (test 12), the processing of the block is terminated, and it is sufficient to extract the information symbols of the block (step 13).

If one at least of the syndromes is not zero, the error locator polynomial a(x) is calculated instep 14, for example according to the Berlekamp-Massey algorithm initialized by σ⁰(x)=1. This algorithm indicates in a conventional manner the blocks for which it estimates that the degree of the error locator polynomial is greater than the degree 2t of the generating polynomial of the code. This condition is tested in step 15. If the degree does not exceed 2t, the next step is the search for the roots of the error locator polynomial σ(x) in step 16, for example according to Chien's algorithm. If the number of roots found is equal to the degree of the polynomial σ(x) (test 17), the next step 18 consists in the calculation of the evaluator polynomial ω(x), according to relation (8). In the next step 19, the Formey algorithm is used to evaluate the amplitudes of the errors, and these amplitudes are subtracted from the corresponding symbols so as to correct them. The information symbols may then be extracted from the block in step 13.

When the erasureless decoding algorithm is stumped, that is to say when the degree of the polynomial σ(x) exceeds 2t (test 15), or when the Chien search does not provide the right number of roots (test 17), the decoder applies the process for decoding with handling of erasures. It begins by calculating the error and erasure locator polynomial (also denoted σ(x) in FIG. 2) from the same syndromes calculated in step 11 and from the initialization polynomial σ⁰(x) (step 20). This calculation is performed according to a Berlekamp-Massey algorithm modified to take erasures into account. The decoder fails if the degree of the locator polynomial σ(x) obtained still exceeds 2t during the test 21. Otherwise, the decoder passes to the search 22 for the roots of the polynomial σ(x) according to Chien's algorithm. The decoder fails again if the number of roots found does not correspond to the degree of the polynomial c(x). Otherwise, it carries out the aforesaid step 18 to determine the error and erasure evaluator polynomial.

As a variant, the evaluator polynomial ω(x) can be calculated during the execution of the Berlekamp-Massey algorithm, in step 14 or 20.

In another embodiment of the decoder, when the decoding with erasures is stumped, the module 5 signals same to the erasures selection module 6. The latter then selects more erasures in the block, and it determines an initialization polynomial σ⁰(x) of higher degree. The decoding algorithm with erasures is executed again using this polynomial σ⁰(x), still with the same syndromes S₁, . . . , S₂ₜ, in a further attempt to correct the block.

1. A method of decoding a block of input symbols (r_{N-1}, r_{N-2}, . . . , r₁, r₀), wherein syndromes (S₁, S₂, . . . , S₂ₜ) are calculated from the block, in conjunction with an error corrector code, and a first process of correction of errors, having the calculated syndromes as input parameters, is applied so as to estimate information symbols, characterized in that in response to an indication of inability to correct by the first process, a second process of correction of errors and of erasures, having the calculated syndromes and at least one erasure position in the block as input parameters, is applied so as to estimate the information symbols.

2. The method as claimed in claim 1, wherein the error corrector code is a Reed-Solomon code.

3. The method as claimed in claim 1 or 2, wherein the first process of correction of errors comprises the calculation of an error locator polynomial based on the syndromes (S₁, S₂, . . . , S₂ₜ), and wherein when the degree of the error locator polynomial exceeds the degree of the generating polynomial of the code, an indication of inability to correct by the first process is generated.

4. The method as claimed in claim 3, wherein the first process of correction of errors comprises a search for roots of the error locator polynomial, and wherein when the number of roots found is not equal to the degree of the error locator polynomial, an indication of inability to correct by the first process is generated.

5. The method as claimed in any one of the preceding claims, wherein, in response to an indication of inability to correct by the second process, the second process of correction of errors and of erasures is applied again while increasing the number of erasure positions in the block which are taken into account in the input parameters, so as to estimate the information symbols.

6. A signal processing device, comprising means (1) for receiving the signal so as to estimate blocks of input symbols (r_{N-1},r_{N-2}, . . . r₁, r₀) and means (2) for decoding said blocks by means of an error corrector code, wherein the decoding means comprise means (3) for calculating syndromes (S₁, S₂, . . . , S₂ₜ) from a signal block and first means (4) for processing the syndromes so as to estimate information symbols, characterized in that the means for receiving the signal (1) are designed to provide information about the reliability of the input symbols of the block, and in that the decoding means (2) furthermore comprise means (6) for determining at least one erasure position in the block on the basis of said information about the reliability, and second means (5) for processing the syndromes and said at least one erasure position, which means are activated in response to an indication of inability to correct by the first processing means (4), so as to estimate the information symbols.

7. The device as claimed in claim 6, wherein the error corrector code is a Reed-Solomon code.

8. The device as claimed in claim 6 or 7, wherein the first processing means (4) comprise means for calculating an error locator polynomial based on the syndromes (S₁, S₂, . . . , S₂ₜ), including means for generating an indication of inability to correct when the degree of the error locator polynomial exceeds the degree of the generating polynomial of the code.

9. The device as claimed in claim 8, wherein the first processing means (4) comprise means for searching for roots of the error locator polynomial, including means for generating an indication of inability to correct when the number of roots found is not equal to the degree of the error locator polynomial.

10. The device as claimed in any one of claims 6 to 9, wherein the receiving means comprise a demodulator (1).
